(19) United States
(12) Patent Application Publication
(10) Pub. No.: US 2026/0285081 A1
(43) Pub. Date: Sep. 24, 2026

(54) METHOD FOR PRODUCING A THREE-DIMENSIONAL STRUCTURE THAT REPRODUCES A CHARACTER STRING, STRUCTURE AND USE OF THE STRUCTURE

(71) Applicant: MODISMO AG, Zurich (CH)

(72) Inventors: Jan Henrik Hansen, Zurich (CH); Daniel Salomon Rasumowsky, Zurich (CH)

(73) Assignee: MODISMO AG, Zurich (CH)

(21) Appl. No.: 17/775,978

(22) PCT Filed: Nov. 11, 2019
(86) PCT No.: PCT/EP2019/080882

§ 371 Date: May 5, 2026

(51) Int. Cl. B44C 3/00; G06F 30/17

(52) U.S. Cl. CPC B44C 3/00; G06F 30/17

(57) ABSTRACT

The present invention relates to a method of manufacturing a three-dimensional structure representing a character string, wherein the characters are arranged relative to each other and formed, wherein offset surfaces of the characters are used, the offset surfaces are arranged so as to contact or overlap each other, a monolith is formed therefrom, and the monolith is formed. The present invention further relates to the provision of various devices and an application for implementing the method.

### SCOPE OF THE INVENTION

The invention relates to a method of producing a three-dimensional structure representing a character string by means of characters arranged and formed relative to each other, and to the structure and its application.

Character strings were known; even before Gutenberg invented printing, monks, in translating the Bible, had arranged letters next to each other. Today, it is widely customary to identify commercial establishments or even private sites, such as homes, using sequences of letters.

These character strings of material are usually designed as a composite held together by a support material, such as a sign, since the individual characters would otherwise fall apart. It is also known to arrange a sequence of isolated characters, with each individual character fixed, for example, by a carrier. This is especially the case when the individual characters, usually letters, are designed to be large so that they can be read from a spacing or are in reasonable proportion to the dimension of the building that they identify. Such character strings are often sent as single orders to specialized stores, which manufacture them as a single object.

There is, however, a need for a process that allows a self-selected text or other character string to be visualized in a simple and inexpensive manner and then produce or have it produced as a physical object, from a self-selected material and in a self-defined size. Another need is for the provision of a three-dimensional structure that renders a character string. Preferably, such a structure should be self-supporting or, alternatively, can be hung on the wall, for example, as a sign or decorative object. At the same time, the process should be cost-optimized, and be able to produce legible structures that can be used, among other things, as a personal credo, souvenir or personal gift.

This problem is solved by a method of the manner mentioned at the beginning, which is characterized by using offset surfaces of the characters, arranging the offset surfaces in such a manner that they touch or overlap, forming a monolith therefrom, and shaping it, and by providing a three-dimensional structure obtainable by the method in accordance with the invention.

The characters can represent letters, such as ASCII characters in any language, or special characters such as emoticons, or combinations thereof. In accordance with one embodiment of the invention, the characters are generated as vector contours or converted into such, or if already available as such, are used in this manner. As far as they are not in vector format, this can be created, for example, by removing or deleting the inner surface of the characters.

In the method in accordance with the invention, offset surfaces of the characters are used, which are created between the contours or main contours and the offset contours of the characters. Then it is convenient and often necessary that the characters or their contours or main contours and offset contours are arranged in such a manner that the desired message is legibly revealed. For this purpose, the horizontally aligned characters or their offset contours can be grouped and moved to the desired line height.

In accordance with one embodiment of the invention, the string may be formed with characters whose size varies. This allows for the inclusion of special accents and emphasis. Regardless of the alignment of the string, such as a block with the same line width or different line length, it has proven favorable to form the monolith in a centered alignment.

in accordance with a preferred embodiment of the invention, an overall offset contour is formed by removing the interior portions of the offset contours that overlap.

It is also convenient that the overall offset contour is formed from the outside curve portions of all offset curves in such a manner that a single contiguous contour is formed.

To achieve the objectives of the invention, it has been found convenient that the contours or main contours and overall offset contours of the characters form a contiguous surface called a “monolith”. This is advantageously converted into a three-dimensional form, whereby the depth or thickness of the material of the three-dimensional structure can be freely selected. It is also possible within the scope of the invention for interior, non-overlapping portions of the offset surfaces to be removed from the monolith, for example, to achieve a quieter, more legible appearance.

In order to achieve solid stability of the three-dimensional structure in accordance with the invention, the volume and focal point can be calculated. Then the character string or structure can be appropriately grouped or aligned around the vertical axis passing through the focal point.

The three-dimensional structure can be formed using subtractive or additive processes. Laser or waterjet cutting is advantageous, however CNC milling, 3D printing, as well as casting, injection molding and other machine manufacturing processes are also suitable. Although the process can be carried out manually by hand, carrying out the process steps up to or including forming by means of a computer is particularly preferred.

The present invention also covers three-dimensional structures obtainable in accordance with one or more of the process claims 1-13. A preferred embodiment of the invention relates to a three-dimensional structure characterized in that the monolith is readable by the volumes of characters cut out of it and delimited by the overall offset contour. This structure may be advantageously centered.

As can be seen from the foregoing, the three-dimensional structures in accordance with the invention are formed without a support material or other composite in the preferred embodiments, and can nonetheless achieve stability and solidity. However, in accordance with the invention, it is not excluded to place a support around, next to or under the three-dimensional structure or character string. This allows decorative aspects to be achieved, such as when the color of the character string contrasts with that of the carrier, or when different material choices produce desired effects.

The materials that can be used within the scope of the invention are not limited. Wood, plastic, glass or metal, such as stainless steel or even aluminum, are advantageous if, for example, value is placed on low weight. When the character string is exposed to the weather, stainless steel, aluminum, as well as glass or weather-resistant plastic are suitable.

The method in accordance with the invention can be advantageously implemented via an application, such as via the internet or locally on a computer. This allows the input of the desired character string, its dimensions, and the desired materials, so that the molding can be directly performed by an appropriately equipped store when used in combination with a resulting manufacturing file. This application can be located on a smartphone, tablet or other computer.

Within the scope of the invention, the following advantages are obtained: First of all, the process allows for the easy and quick handling of the necessary steps, which enables the design and visualization of desired monoliths for persons who are familiar with CAD (Computer Aided Design) software and CNC production, i.e. computer-controlled machine tools.

Within the context of a computer application, the process also enables anyone—even persons without knowledge of CAD applications or manufacturing processes—to design a desired object, visualize it, easily customize it and then order it on demand, all within a few minutes.

In order to achieve the desired design and functional effects, the user can “play” with the typeface, its format, dimensions etc., until they obtain the satisfactory result and if necessary, the desired price, which can be automatically calculated and displayed, and can thus help in setting the above criteria.

The method in accordance with the invention and the structure that is obtainable from it are not only versatile, but also allow savings of material and thus, weight and costs. The volume required to print the characters is optimized by the fact that all characters are readable as a cut-out volume, and the actual material required for the monolith can thus be kept to a minimum.

The invention is explained below in the context of a preferred embodiment, which, however, is not to be interpreted restrictively. In particular, it is not mandatory for all the steps shown to be carried out in the method in accordance with the invention and/or in the sequence shown. For example, it should be mentioned that the “make-block” design or the removal of interior surfaces between characters may be omitted, etc.

### Creating a Character String

An arbitrary character string (=text, and/or characters) is defined, e.g. via a keyboard on a device with a screen (cell phone, tablet, desktop computer, etc.).

Example

### Distributing Characters to Lines

Theoretically, any arrangement of characters on lines is possible. For short sentences, phrases, and quotations, a distribution of one word per line is advantageous, as it results in some height expansion.

Example

### Converting Characters to Contours

Normally, texts are created on computers as so-called “fonts” (such as Truetype, and in other standard formats), which means that they are not readily editable and usable.

Therefore, it is advantageous to perform a conversion into “contours”, i.e. lines and/or curves that are geometrically useful for the following steps.

Example

| | |
|---|---|
| Buchstabe/Zeichen, z.B. | Letter/character, e.g. |
| ASCII-Standard | ASCII Standard |
| Kontur, vorteilhaft in | Contour, advantageously in |
| Vektor-Format = als | vector format = as geometric |
| geometrische Linie/Kurve/ | line/curve/radius |
| Radius | |

### Editing Composite Contours

To be able to use characters that consist of more than one contour, they can first be edited as follows before the subsequent steps.

### EXAMPLES

a) Eliminating Contours Lying within the Main Contour

| | |
|---|---|
| Innenliegende Kontur | Inner contour |
| Haupt-Kontur | Main contour |
| Nur Haupt-Kontur verbleibt | Only main contour remains |

b) Grouping Outer Contours with the Main Contours.

This means that all contours belonging to the character will be edited together from now on.

| | |
|---|---|
| Aussenliegende Konturen | External contours |
| Haupt-Kontur | Main contour |
| Gruppierte Konturen | Grouped contours |

### Note

There are fonts where the inner contours are already connected to the main contours for cutting applications in such a manner that step a) and in some cases also step b) can be omitted. Therefore these steps are not mandatory.

### Creating Offset Contours

For the characters, a so-called offset contour is created with a spacing A to the main contour of the character, which can be selected by the user, resulting in an offset area between the two contours. The corners of the offset contours can be executed in different ways, such as mitered as in the example below, or rounded, e.g. radially.

The offset contours and offset surfaces serve two subsequent steps:
a) The calculation of the character spacing
b) The creation of the overall offset contour

| | |
|---|---|
| Haupt-Kontur | Main contour |
| Versatz-Flaeche | Offset surface |
| Ecke der Versatz-Kontur | Corner of offset contour |
| Versatz-Kontur | Offset contour |
| Abstand A | Distance A |

Examples of the Offset Contour Corners

| | |
|---|---|
| Versatz-Kontur | Offset contour |
| Haupt-Kontur | Main contour |
| Versatz-Kontur mit Ecken auf | Offset contour with corners on mitre |
| Gehrung | |

| | |
|---|---|
| Haupt-Kontur | Main contour |
| Versatz-Flaeche | Offset surface |
| Ecke der Versatz-Kontur | Corner of offset contour |
| Versatz-Kontur | Offset contour |
| Abstand A | Distance A |

Examples of the Offset Contour Corners

| | |
|---|---|
| Versatz-Kontur | Offset contour |
| Haupt-Kontur | Main contour |
| Versatz-Kontur mit Ecken auf | Offset contour with corners |
| Gehrung | on mitre |
| Versatz-Kontur mit | Offset contour with rounded |
| abgerundeter Ecke (=Radius) | corner (=radius) |

### Calculating Horizontal Character Spacing

Initially, all characters are positioned with their lower left corner at the origin. Now each character is moved from the origin of the coordinate system within its line until it is to the right of its left neighboring character and has the correct spacing from it.

The correct spacing is defined by a suitable overlap of the offset area around each character so that, on the one hand, readability and, on the other hand, subsequent cohesion can be ensured.

Example

| | |
|---|---|
| Ursprung | Origin |
| Ueberlappung | Overlap |

### Moving Rows to the Correct Height

All lines with their now horizontally aligned characters are now still on top of each other, with their lower left corner at the origin of the coordinate system.

The characters belonging to a line are grouped and moved to the appropriate height, including appropriate line spacing between lines.

Example

| | |
|---|---|
| Alle Zeilen uebereinander im | All lines over each other |
| Ursprung | in origin |
| Ursprung | Origin |
| Zeilen-abstand | Line distance |

### Horizontal Alignment of the Lines

Centered alignment of the rows is suggested as a standard in this embodiment, since it has the advantage of keeping the objects balanced and less likely to fall over in free-standing applications.

Example

| | |
|---|---|
| Mittelachse | Central axis |

### Option: “Make Block”

This option allows automatic scaling of all lines to the same width, regardless of the number of characters. Since this scaling preferably occurs proportionally, the lines change their respective heights accordingly depending on their width.

Example

| Normalfall: | Normal case: |
|---|---|
| Gleiche Schriftgroesse auf | Same font size on all lines |
| allen Zeilen | |
| Zeilenbreite variiert | Line width varies |
| Option “Make Block”: | Option “Make Block”: |
| Schriftgroesse der Zeilen | Font size of lines varies |
| variert | |
| Breite aller Zeilen gleich | Width of all lines is the |
| | same |
| Zeilenbreite | Line width |

### Creating Overall Offset Contours

After all characters—including their offset contours—are in the correct position, the so-called overall offset contour is created. This consists of the respective outer contour components of all offset contours. That is, these contour parts are joined to form a single new contour that is coherent.

Example

| | |
|---|---|
| Einzelne Versatz-Konturen | Individual offset contours |
| Zusammenhaengende Gesamt- | Continuous overall offset |
| Versatz-Kontur | contours |

### Variant 1 For Internal Parts of the Offset Contours

All internal parts of the offset curves are deleted.

Example

| | |
|---|---|
| Gesamt-Versatz-Kontur | Overall offset contour |

### Variant 2 For Internal Parts of the Offset Contours

The areas of the offset surfaces that do not overlap become additional openings that remain within the overall offset contours. Both variants have advantages:
Variant 1: better readability, calmer appearance
Variant 2: less material=less weight and cost
   Example

| | |
|---|---|
| Verbleibende Oeffnungen | Remaining openings |
| Gesamt-Versatz-Kontur | Overall offset contours |

### Creating a Monolith Surface

A single continuous surface can now be created between the main character contours and the overall offset contours. Only variant 1 is shown in the example; an analogous process applies to variant 2.

Example

| | |
|---|---|
| Haupt-Konturen der Zeichen | Main contours of characters |
| Gesamt-Versatz-Kontur | Overall offset contour |
| Monolith-Flaeche | Monolith areas |
| Zusammen-haengende Flaeche | Continuous area |

### Creating a Monolith Volume

The created cohesive surface is now optionally extruded, i.e. expanded into the third dimension to obtain a spatial volume with a depth D. This depth D is variable and can be adjusted at any time.

Example

| | |
|---|---|
| Monolith-Flaeche | Monolith areas |
| (=zusammen-haengendes | (=continuous area) |
| Flaeche) | |
| Monolith-Volumen | Monolith volume |
| (=Zusammen-haengendes | (=Continuous volume) |
| Volumen) | |
| Tiefe T | Depth T |

### Calculating Volume and Focal Point

In the consideration and subsequent production and a model of the monolith object, two favorable calculations are now made:

### 1) Volume Content

The resulting volume content is calculated in order to calculate the weight and material requirements for production.

### 2) Focus

The focal point of the volume is calculated; this helps to easily view the model of the monolith, as one can optimally rotate the subsequent display around it without losing sight of the object.

In addition, the focal point is useful for further applications, for example for a hanging object, for which—for example—a suspension eyelet can be placed at the exact location of the monolith in a further step, where it will remain in balance, and which will be on the vertical axis of the focal point.

Example

| | |
|---|---|
| Schwerpunkt | Focus |
| Vertikale Achse des | Vertical axis of focus |
| Schwerpunkts | |

### Model Display

The three-dimensional model can now be viewed in a selected material, with light and shadow cast from any angle and spacing. This allows the properties of the object to be checked and adjusted if necessary, such as the size, depth, material and width offset area.

### Embodiment Options:

The object can be used in variants, such as
1) for hanging (chain, pendant, mobile etc.)
2) as a container for storing objects.
3) to be implemented and optionally displayed as a utility object, for example, a lamp, bottle (hollow body), etc.
   Example

| | |
|---|---|
| Navigation um das Objekt | Navigation around the object |

### Calculating the Price Interactively

On the basis of all currently known values, the process allows an automatic price calculation (e.g. within the scope of an application) which is visible during the design in addition to the object. When the object is adjusted, it updates itself, so that an adjustment of the object properties can also be made in accordance with the price criterion; this can often be helpful and would otherwise always have to be recalculated at great effort.

Below is a simplified list of the relevant criteria that are used in the formula for calculation, which may vary depending on the type of manufacturing.

### Example

1) Production with Laser/Waterjet Cutting (Subtractive Methods)
a) Material costs

$$Required material area * material thickness = material volume$$

$$Material volume * material price / volume = material cost$$

b) Machinery costs
   Activation of machine

$$Length of cutting path * cutting speed = cutting time$$

$$Cutting time * machine cost / time = machine cost$$

c) Possibly other costs such as painting, administration, etc.
d) Margin
e) Shipping (shown separately)

### 2) Manufacturing by 3D Printing (Additive Process)

a) Material cost: effective print volume is relevant
b) Machinery costs
   Activation of machine
   Printing time*machine cost/time
c) Possibly other costs such as painting, administration, etc.
d) Margin
e) Shipping (shown separately)

### Order to Manufacturer

If the user or customer is satisfied with the result and wants to order it, a normal purchase process takes place, as known from other applications or web stores, which involves depositing the customer data such as name, address, etc. and paying the purchase price.

The subsequent dispatch of the order to a manufacturer is preferably carried out automatically by the application. This can be done, for example, in the form of an email that contains all information necessary to process the order, as well as the file for production on their machine tool, for example, in the format “.dxf” or another suitable format.

Example

| | |
|---|---|
| Applikation MODISMO | Application MODISMO |
| Automatische email | Automatic email |
| Empfaenger | Recipient |
| Email: modismo@partner-firma- | Email: modismo@partner-firma- |
| xy.com | xy.com |
| Bestellung: | Order: |
| Auftrag-Nr.: 35 | Order no.: 35 |
| Text: “All you need is less” | Text: “All you need is less” |
| Hoehe | Height |
| Breite | Width |
| Tiefe | Depth |
| Material: MDF | Material: MDF |
| Gewicht: 750 Gramm | Weight: 750 grams |
| Datum: 19 Okt. 2019 | Date: Oct. 19, 2019 |
| Zeit: 8:02 Uhr | Time: 8:02 am |
| Verkaufspreis: 98 Euro | Sale price: 98 Euro |
| Kunde: | Customer: |
| Name: Hans Mustermann | Name: Hans Sample |
| Adresse: Musterstrasse 11 | Address: Sample Street 11 |
| Ort: Musterstadt | Place: Sample City |
| PLZ: 81925 | Postal code: 81925 |
| Email: kundenname@gmail.com | Email: kundenname@gmail.com |
| Anhang: | Attachment: |
| Produktionsdatei_Auftrag- | Production file_order |
| Nr_35.dxf | no._35.dxf |

The embodiment of the present invention and further aspects have been explained above with reference to FIGS. 1 to 9.

Aspects relating to the implementation of the invention at the device level and process sequences associated therewith are now described with reference to FIGS. 10 to 15.

FIG. 10 shows a schematic diagram of a device for implementing the invention at the device level.

As shown in FIG. 10, the device in accordance with the invention contains different functional units. This includes a user terminal 10 by means of which an interface to the user of the system in accordance with the invention is realized. A 3D forming device 20 and a computing device or computer 30, which may optionally be connected to a database 50, are also provided.

As shown in FIG. 10, the computing device 30 includes at least one interface 32 that may be suitably configured depending on the application; for example, as a wireless interface to a cell phone if the user terminal is a cell phone. The interface 32 is suitable for exchanging information not only to the user terminal device 10, but also to the 3D forming device 20.

As shown in FIG. 10, the computing device 20 furthermore includes at least one processor 34 which is connected to interface 32 and a memory 36 which is connected to at least one processor 34. For example, the memory 36 can be a read-only memory ROM, a flash ROM, a random access memory RAM, or a dynamic RAM DRAM or static RAM SRAM. The memory functionality may likewise be supported by the database 50. For example, the database can hold 50 different typographies or preconfigurations for the 3D structure.

As shown in FIG. 10, the memory 36 includes a suitably configured program source code which is executable by the at least one processor 34 for implementing the functionality of the computing device 30 as described below. This functionality is referenced below in the form of various units that do not represent individual hardware components of the computing device 30, but rather reflect the functionality that is achievable when an appropriately configured program source code is executed by the at least one processor 34.

As shown in FIG. 10, the memory 36 comprises at least a suitably configured program source code for implementing a character processing unit 38, an offset contour processing unit 40, a monolith generation unit 42, and a 3D structure generation unit 44.

It should be mentioned that although different units of the system in accordance with the invention are shown as separate devices in FIG. 10, the present invention obviously also covers a system in which these described devices are either fully integrated or partially integrated. This depends on the particular application; for example, whether 3D generation is exclusively and solely under the control of the manufacturer, or is implemented as a web application. In the latter case, the functionality of the computing device 30 may also be moved to the cloud, for example.

FIG. 11 shows a flowchart of the general operation of the device shown in FIG. 10 for implementing the invention at the device level.

As shown in FIG. 11, in a first step S10 which is performed by the character processing unit 38, processing of character strings that are fed to the computing device 30 via the interface 32 takes place within the scope of the invention.

This is followed by step S20, executed by the offset contour processing unit 40, to create the offset contour as specified above.

As shown in FIG. 11, step S20 is followed by step S30, which is performed by the offset contour processing unit 40 to arrange the offset contour generated in step S20.

As shown in FIG. 11, this is followed by step S40, which is performed by the monolith generation unit 42 to form a monolith.

Finally, as shown in FIG. 11, step S50, performed by the 3D structure generation unit 44, follows to generate a 3D structure in accordance with the desired character string.

FIG. 12 shows a flowchart illustrating individual steps performed by the character processing unit 38 when processing character strings.

As shown in FIG. 12, step S10 for processing a character string is divided into the creation of a character string, step S10-1, and the distribution of created character strings into individual lines, step S10-2.

Within the scope of the present invention, any formats for characters, for example ASCI, as well as options for the creation of character strings and their input are supported.

Options for designing the user device 10 to create the character string include graphical user interfaces, a keyboard, speech recognition systems and the use of preconfigured strings, for example.

Furthermore, the distribution of characters into different lines, section S10-2, is supported in a variable manner. It is not mandatory for individual character strings of each line to form a word; combinations of different words in a line, partial words in a line, etc. are also possible.

FIG. 13 shows a flowchart illustrating individual steps performed in the creation of offset contours and offset surfaces by the offset contour processing unit 40.

In general, and as described above, the creation of offset contours as well as offset surfaces requires a conversion of characters to contours, step S20-1, a processing of composite contours, step S20-2, as well as the creation of the offset contours, step S20-3.

As explained above, the conversion of contours includes, for example, eliminating inside contours, or grouping outside contours into a grouped contour. The offset contour is then created with frame formation on the basis of a main contour, wherein corresponding parameters for the width of the offset contour, and the configuration of the offset contour can be freely selected in accordance with the invention.

FIG. 14 shows a flowchart illustrating individual steps that are performed in the arrangement of offset surfaces by the monolith generation unit 42. As shown in FIG. 14, in a step S30-1, characters or words assigned to a special line must first be arranged in that line. This is done by calculating horizontal character spacing. The result is a line with different lines, represented by offset contours that overlap appropriately.

As shown in FIG. 14, the vertical alignment of the lines is then performed, step S30-2, wherein line spacing can be suitably parameterized. This is followed by the horizontal alignment of the lines, step S30-3, for example left-aligned, right-aligned, centered, in accordance with the user's specifications. Optionally, the rows can be formed into a rectangular block structure by performing automatic scaling of the rows, step S30-4.

Finally, as shown in FIG. 14, the creation of an overall offset contour follows in step S30-5. Here the objective is to create a continuous surface or the monolith surface as specified above.

FIG. 15 shows an illustration of individual steps performed during the generation of the 3D structure by the structure generation unit 44.

As shown in FIG. 15, the generation of the 3D structure is divided into the calculation of the volume content and the focal point of the 3D structure, step S50-1, the display of the model, step S50-2, the determination of production parameters, step S50-3, and the generation of a production order S50-4. The result of the last step S50-4 is forwarded via the interface 32 to the 3D shaping device 20, for example to an order taker who implements the result of the 3D structure generation by means of 3D printing, milling, or other suitable shaping processes.

Aspects of the implementation of the invention at the device level and associated process sequences are explained above with reference to FIGS. 10 to 15.

The following, with reference to FIGS. 16 to 22, will now describe aspects of the present invention insofar as they are related to the implementation of the present invention in the form of an application or app.

FIG. 16 shows a client-server constellation that forms the basis for the use of the present invention in the form of an application.

As shown in FIG. 16, the implementation of the present invention is carried out by means of an application using a user terminal 60 interacting with a server 70 that is operated, for example, in a cloud. in accordance with the invention, the interaction of the user terminal 60 with the server 70 is representable by means of various communication mechanisms, such as the internet, wireless radio communication, combinations thereof, etc.

FIG. 17 shows a schematic diagram of a user terminal 60 in which the present invention is used in the form of an application.

As shown in FIG. 17, the user terminal 60 includes a display 62, a processor 64, and a memory 66.

As shown in FIG. 17, the memory 66 includes a suitably configured program source code which is executable by at least one processor 64 for implementing the functionality of the user terminal 60 as described below. This functionality is referenced below in the form of various entities that do not represent individual hardware components of the user terminal 60, but rather reflect the functionalities achievable when an appropriately configured computer program is executed by the at least one processor 64.

As shown in FIG. 17, memory 66 contains at least a suitable program source code for implementing an application configuration unit 68 and an application application unit 69.

FIG. 18 shows a flowchart illustrating individual steps to be performed during installation of the application in accordance with the invention.

As shown in FIG. 18, in a first step S60 which is executed by the application configuration unit 68 within the scope of the invention, an application or computer program is downloaded that implements the method in accordance with the invention, insofar as it is related to the design of the character string, by means of software.

As shown in FIG. 18, this is followed by step S70, also executed by the application configuration unit 68, for installing the downloaded application into the memory 66.

As shown in FIG. 18, this is followed by step S80, executed by processor 64, to execute the application as explained in greater detail below.

FIG. 19 shows a flowchart illustrating individual steps performed in executing the use of the invention at the user terminal 60.

As shown in FIG. 19, in a first step S90 which is executed by the application application unit 69, an interaction screen is displayed to the user within the scope of the invention. This is followed—executed by the application use unit 69, by the input of text in a step S100, supplemented by the input of design parameters in a step S110, also executed by application use unit 69.

As shown in FIG. 19, step S110 is followed by step S120, which is executed by processor 64 to convert the input of production data. In accordance with the present invention, production data can be converted in numerous ways. A first, rudimentary form is to appropriately format the entered text as well as the entered design parameters, and forward them to the cloud. Alternatively, it is conceivable to process the input information already located on the user terminal in accordance with the above-described method for producing a 3D structure to such an extent that only the formation into a 3D structure by means of a corresponding production device needs to take place after the production data are transferred. In addition, the present invention covers variations in which a hybrid form of the described alternatives, namely the simple forwarding of input data or complete implementation in a monolith, can be implemented. This is particularly advantageous for constellations where the user desires an iteration of design steps, allowing them to experiment with design parameters locally on the user terminal 60.

Finally, as shown in FIG. 19, in a step S130 which is carried out by a communication means shown in FIG. 18, the production data is transmitted to the server 70 shown in FIG. 16 or another suitably designed computing device that is operated, for example, directly by the manufacturer of the 3D structure.

As shown in FIG. 20, the user interface has a text input field by means of which a character string can be entered. Here, within the scope of the present invention, there are no restrictions with respect to number of words, vocabulary, language, etc.

As shown in FIG. 20, the user interface allows the user of the method in accordance with the invention to track the current status of the design result at any time. Suitable input fields for the height, depth, frame size for the offset contour, option of a block formation, character set, as well as for the manufacturing material allow the user to experiment with design parameters in order to optimally convert the design result to a user-specified objective.

It should be mentioned that the design of the user interface shown in FIG. 20 is, of course, to be understood as merely exemplary. The parameters for the design can be modified, extended, or supplemented at any time. This also applies to the mechanisms for interaction with the user, for example, by means of a keyboard, speech recognition, etc.

It should also be noted that, within the scope of the present invention, the user interface may be provided in various embodiments specific to a particular subtask:
Size selection in accordance with XS to XL, or customized with manual dimension input.
Material selection: Display of material options with prices.
Selection of the layout in the block layout.
Summary display of the selected design information, optionally with pricing information, before sending the production order.

FIG. 21 shows a schematic diagram of a server by means of which the application of the present invention is supported after transmission of production data from the user terminal 60.

As shown in FIG. 21, the server 70 includes at least one interface 72, which may be suitably configured depending on the use; for example, from wireless interfaces to a cell phone or as an internet connection. The interface 72 is suitable not only for exchanging information with the user terminal 60, but also for exchanging information with the 3D forming device 20, as shown in FIG. 10.

As shown in FIG. 21, the server 70 also includes at least one processor 74 coupled to the interface 72 and a memory 76 coupled to the at least one processor 74. The memory 76 is, for example, a ROM, RAM, DRAM, or SRAM which is suitably adapted to the requirements of the application.

As shown in FIG. 21, the memory 76 contains the suitably configured program source code or computer program executable by the at least one processor 74 for implementing the functionality of the server 70 described below. This functionality is in turn referenced by units that are implemented when the appropriately configured computer program modules are executed. As shown in FIG. 21, memory 76 contains at least a suitably configured program source code for implementing an order processing unit 78, a transformation unit 80, and a production order generation unit 82.

FIG. 22 shows a flowchart illustrating individual steps performed using the server shown in FIG. 21. A first step S140, performed by the interface 72, is to receive production data as generated on the user terminal 60 side. These are then suitably stored in memory 76 for subsequent processing in a step S150.

After step S150, step S160 follows, executed by order processing unit 78 and transformation unit 80. Here, the order processing unit 78 performs processes related to procedural or commercial aspects of a product order. This means, for example, setting production prices, delivery deadlines, etc.

Another sub-step of step S150, performed by transformation unit 80, is to suitably transform the information generated via the user terminal 60 into data directly suitable for producing a 3D structure. The mode of operation of transformation unit 80 depends on the extent to which design information is generated by the user terminals 60. For example, if user terminal 60 should only input text and design parameters, the method in accordance with the invention for producing the monolith must be fully implemented in server 70 by means of transformation unit 80. On the other hand, if the complete monolith should be included in the information received by server 70, transformation unit 80 only needs to perform the step of preparing for shaping of the 3D structure before corresponding design data is then forwarded to the 3D structure manufacturing device.

As shown in FIG. 22, another step S160 performed by the production order generation unit is to combine the order processing data and the production data and send the corresponding production order to the manufacturer of the 3D structure.

Although the present invention has been described with reference to the drawing and preferred embodiments, it is evident that the present invention is equally capable of being implemented by a person skilled in the arts without departing from the scope of protection of the present invention as defined by the subject matter of the claims. For example, the described functionalities can be implemented in software, hardware or in a combination thereof.

Accordingly, it is not intended for the scope of protection of the claims to be construed in a limited manner by the foregoing description, rather, the interpretation should be determined by reference to all equivalents accessible to a person skilled in the art within the meaning of the present invention.

### FIGURES

Advantageous embodiments of the invention are shown in the following figures.

FIG. 1 illustrates the scaling

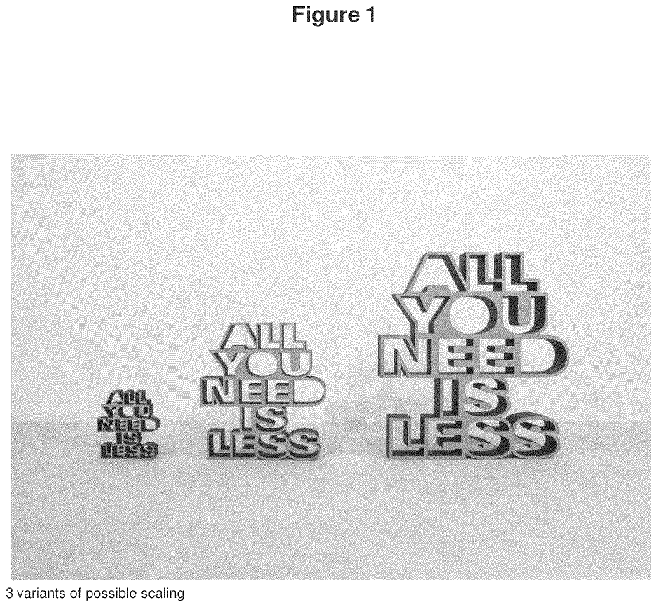

FIG. 2 shows options for positioning

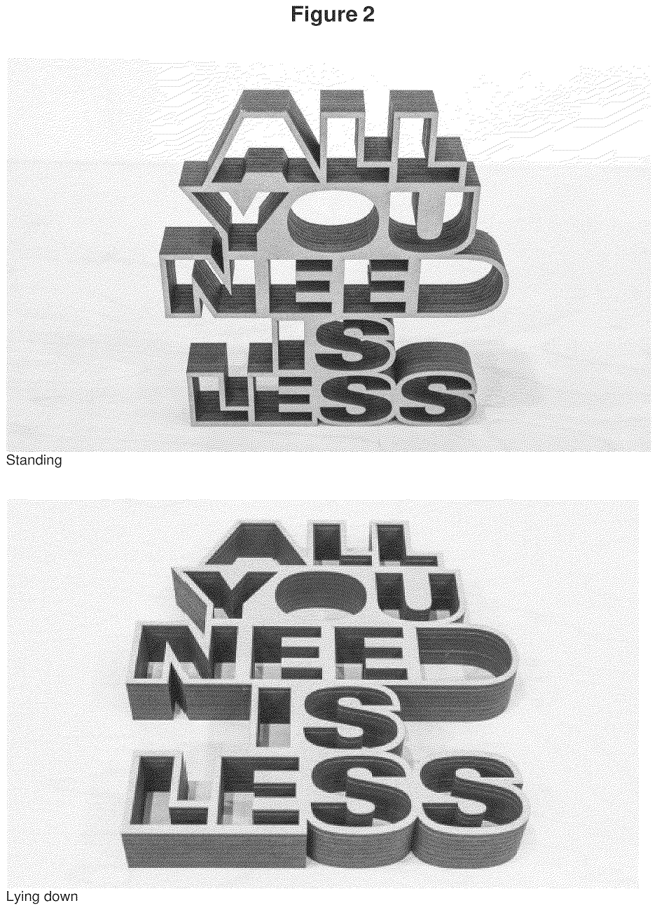

FIG. 3 shows hanging decorative objects

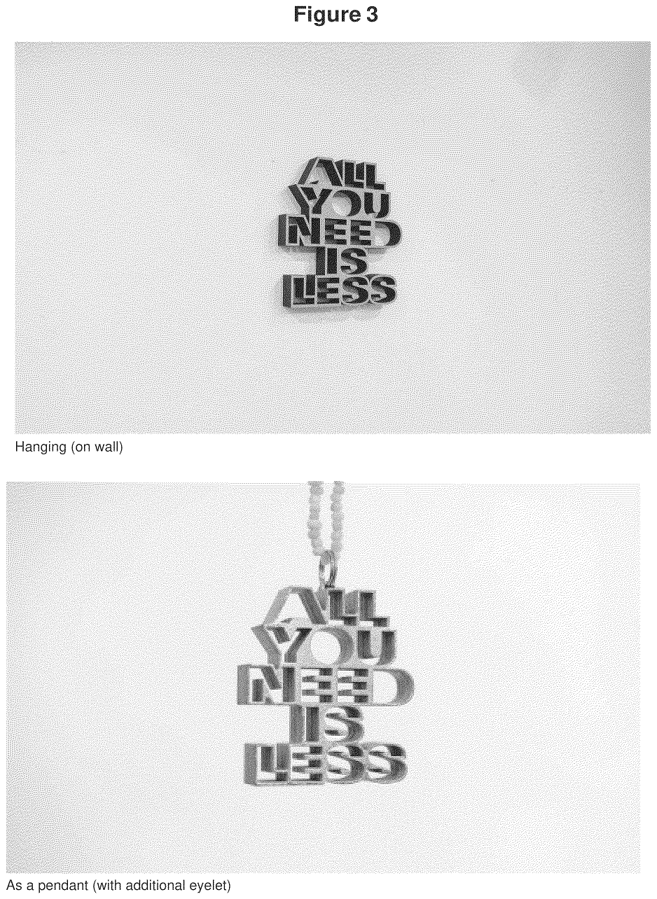

FIGS. 4, 5, 6 show the structure as a container and/or as its lid, or inserted therein

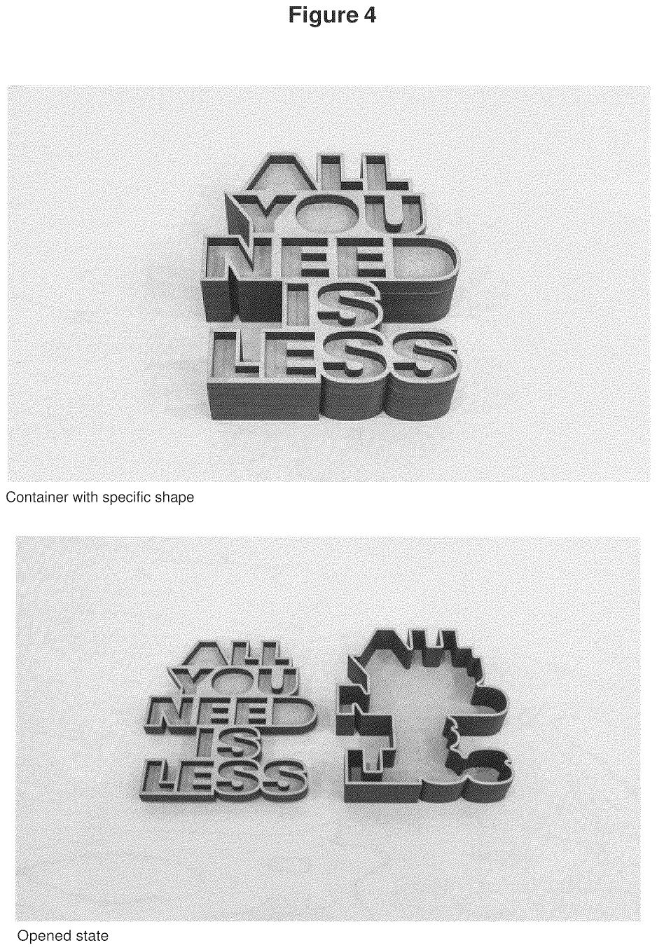

FIG. 7 shows a “make-block” embodiment

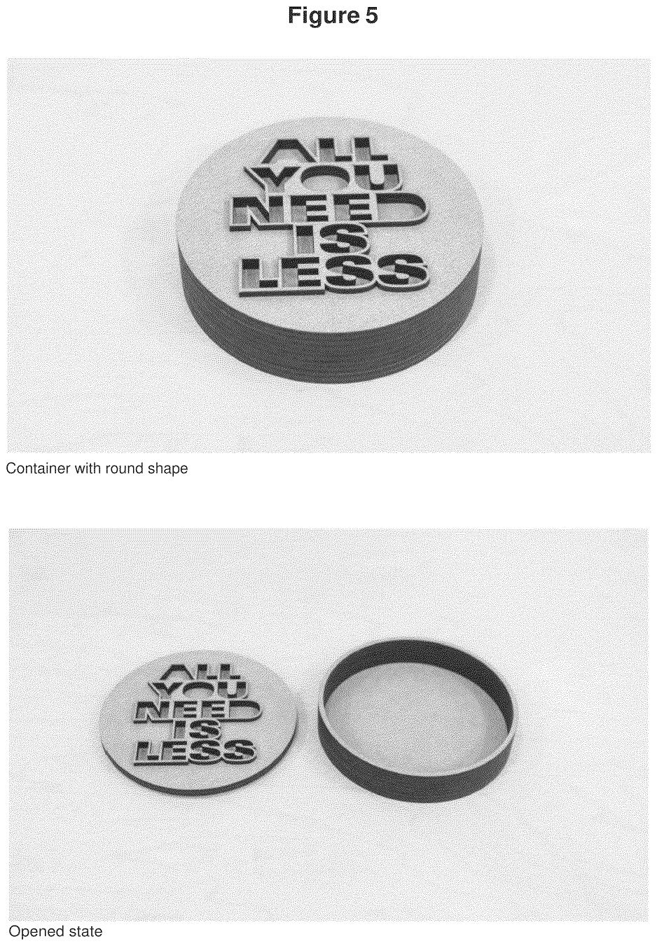

FIG. 8 shows CAD (=Computer Aided Design) modeling, fabrication by laser cutting, and the desired volume of the monolith by gluing individual layers

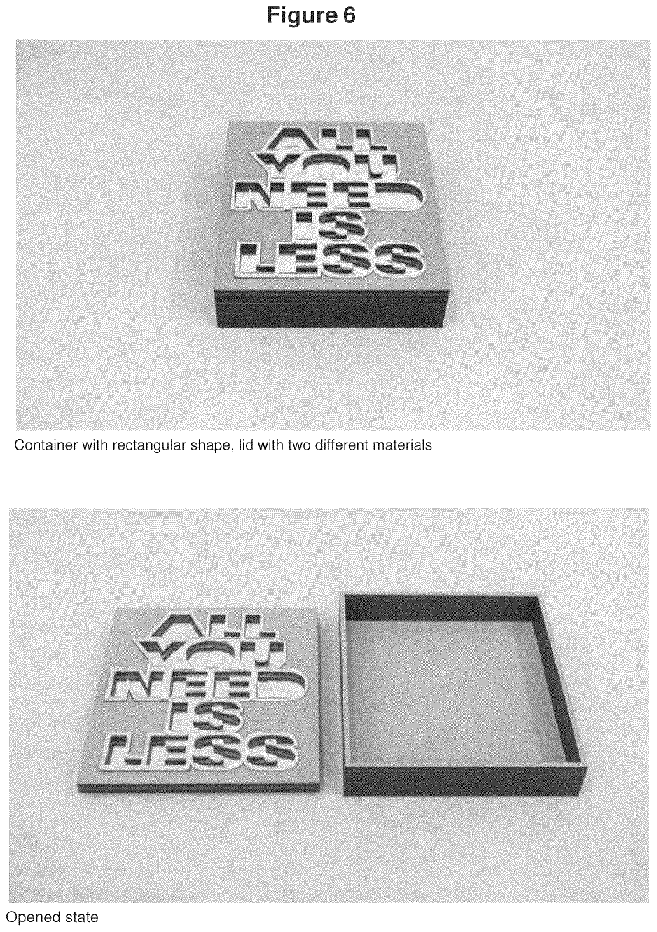

FIG. 9 shows options for material and color selection

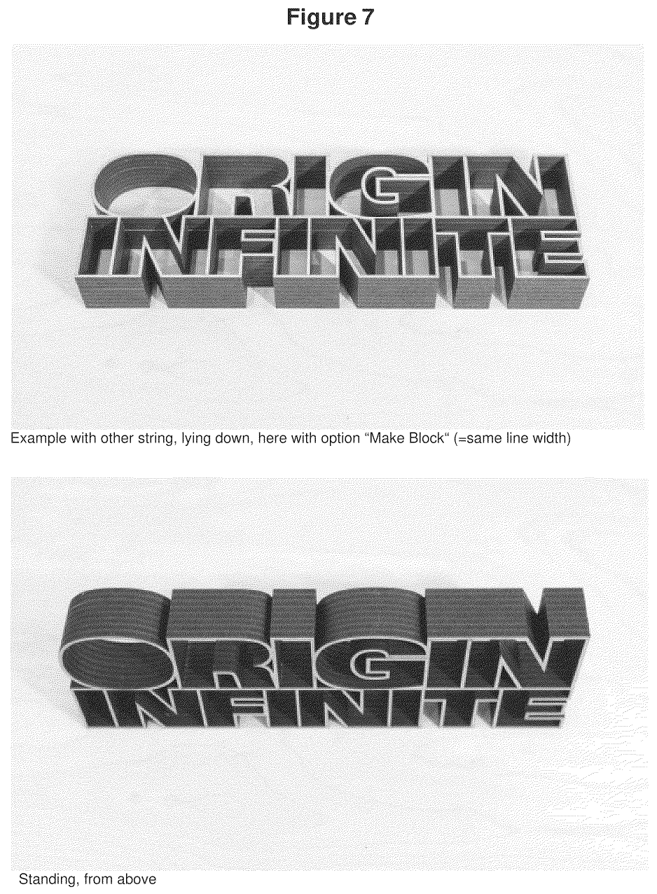

FIG. 10 shows a schematic diagram of a device for implementing the invention at the device level.

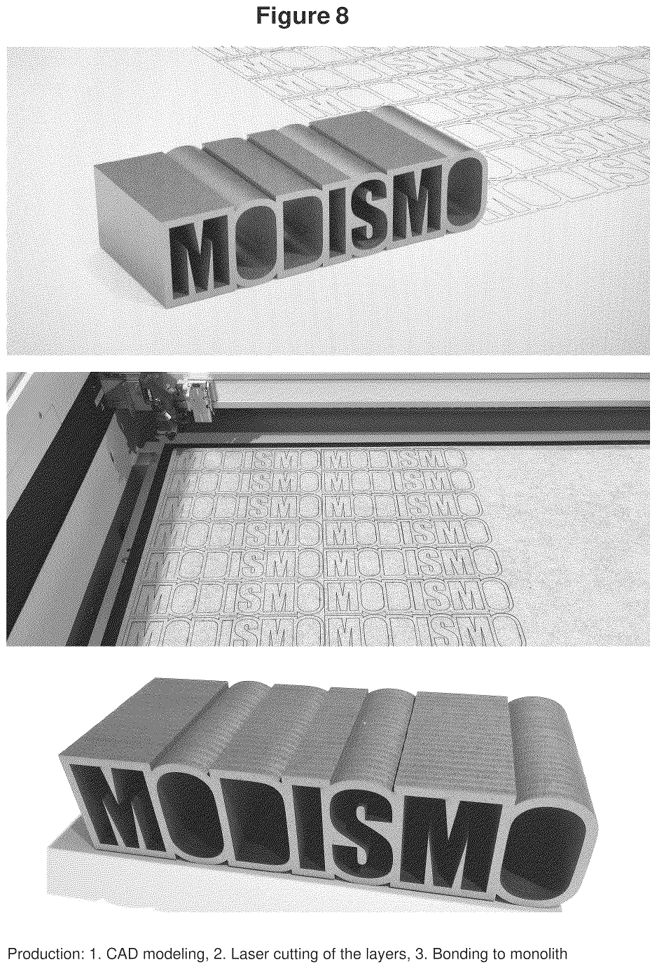

FIG. 11 shows a flowchart of the general operation of the device as depicted in FIG. 10.

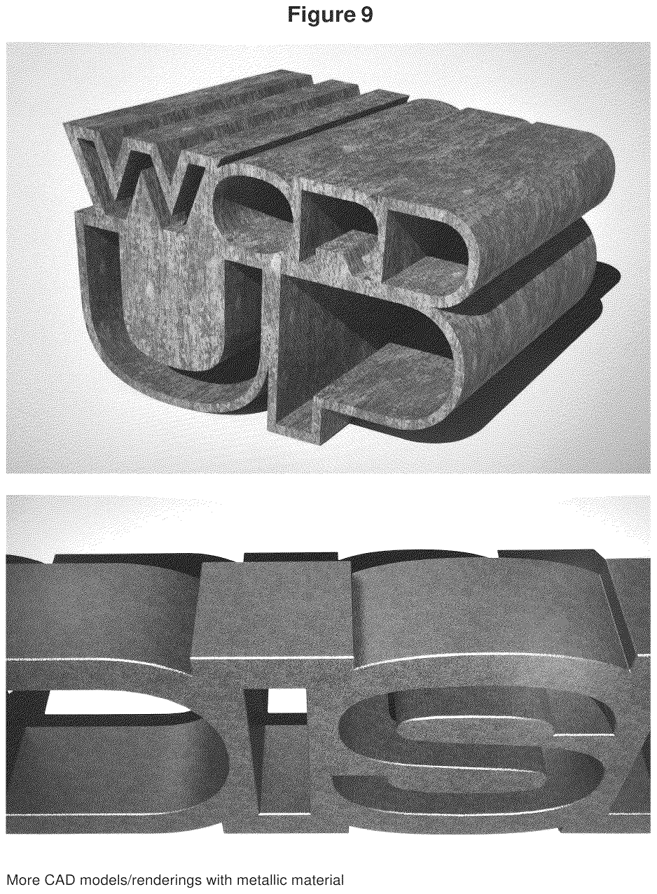

FIG. 12 shows a flowchart illustrating individual steps performed in processing character strings.

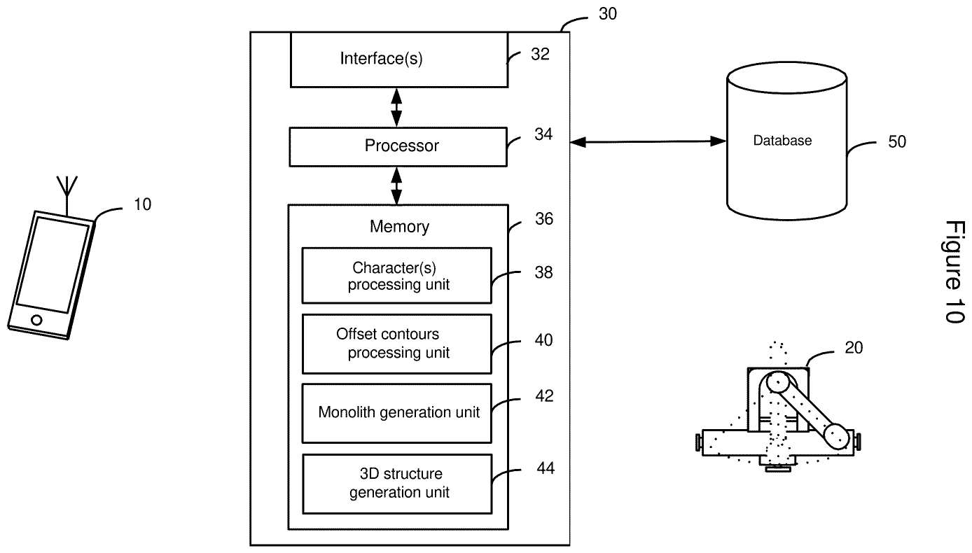

FIG. 13 shows a flowchart illustrating individual steps performed in the creation of offset contours and offset surfaces.

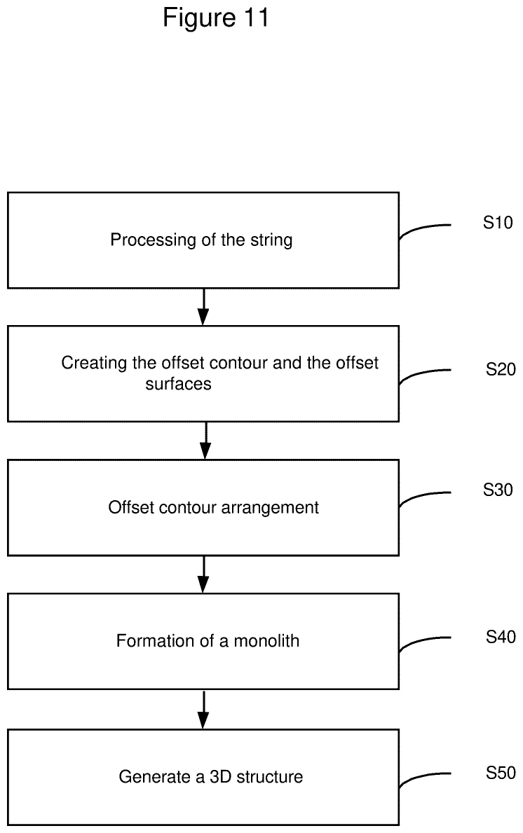

FIG. 14 shows a flowchart illustrating individual steps performed in the arrangement of offset surfaces

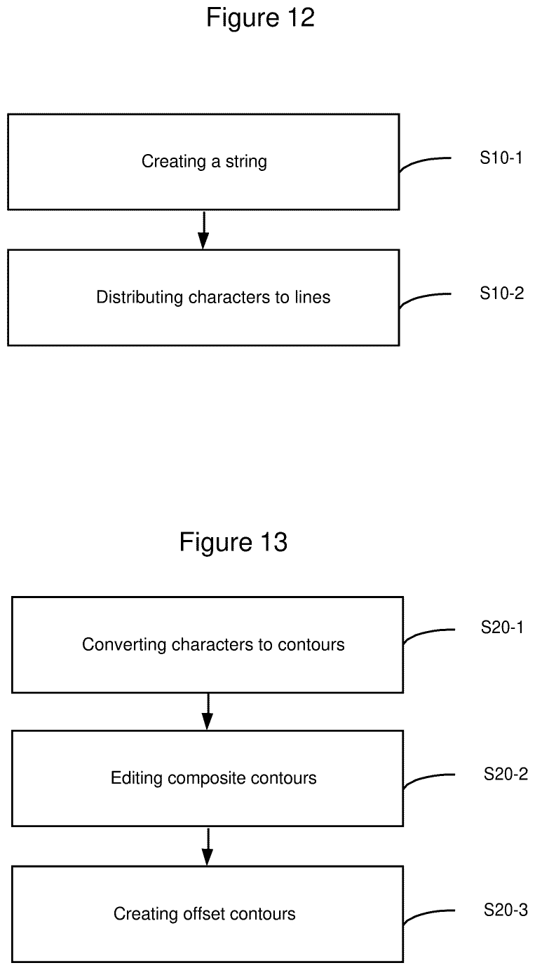

FIG. 15 shows a flowchart illustrating individual steps performed in generating a 3D structure

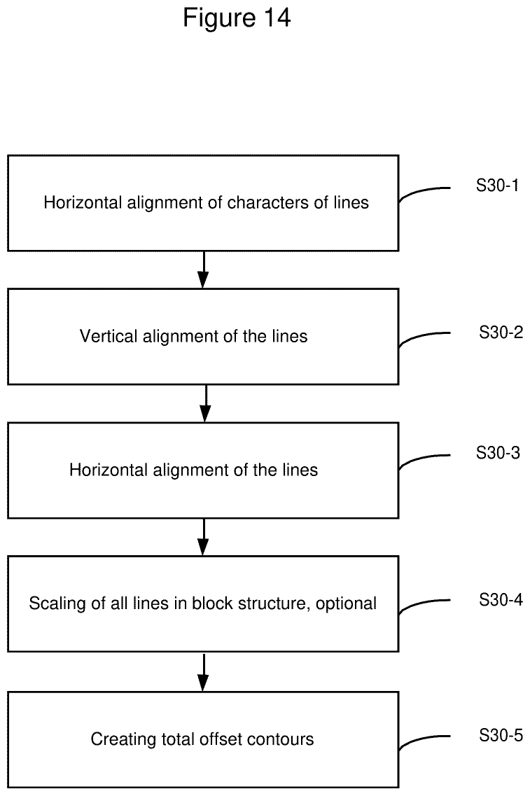

FIG. 16 shows a client-server constellation, which is the basis for the application of the present invention in the form of an application.

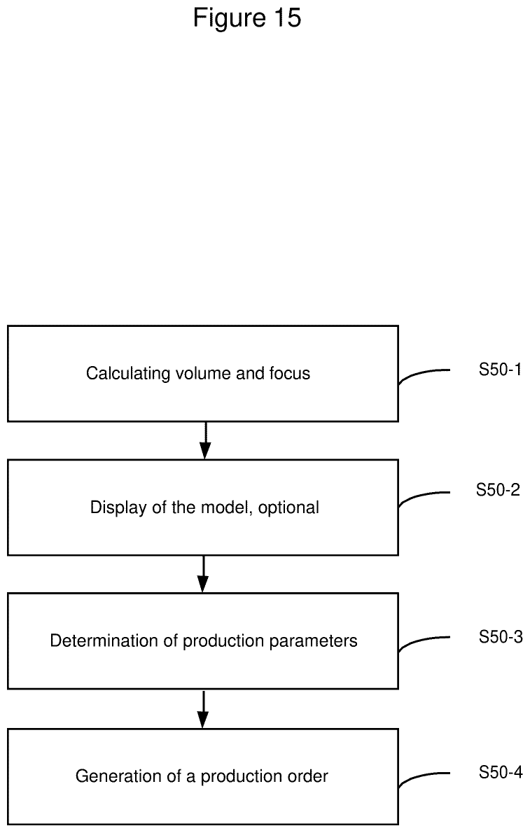

FIG. 17 shows a schematic diagram of a user terminal device in which the present invention is applied in the form of an application.

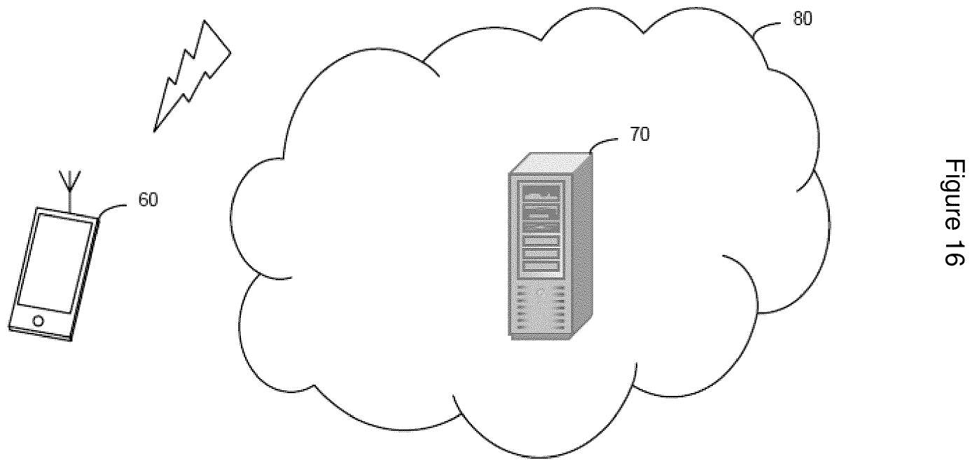

FIG. 18 shows a flowchart illustrating individual steps performed during the installation of the application in accordance with the invention.

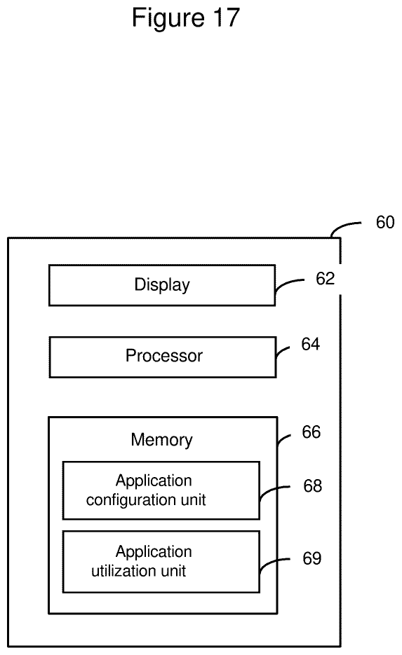

FIG. 19 shows a flowchart illustrating individual steps performed in the embodiment of the application in accordance with the invention.

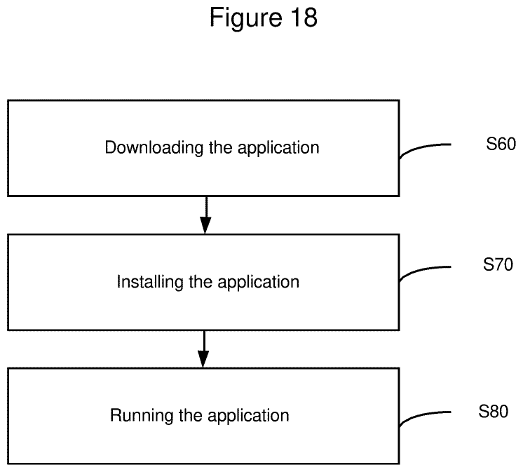

FIG. 20 shows an example of the user interface formation used to input design information

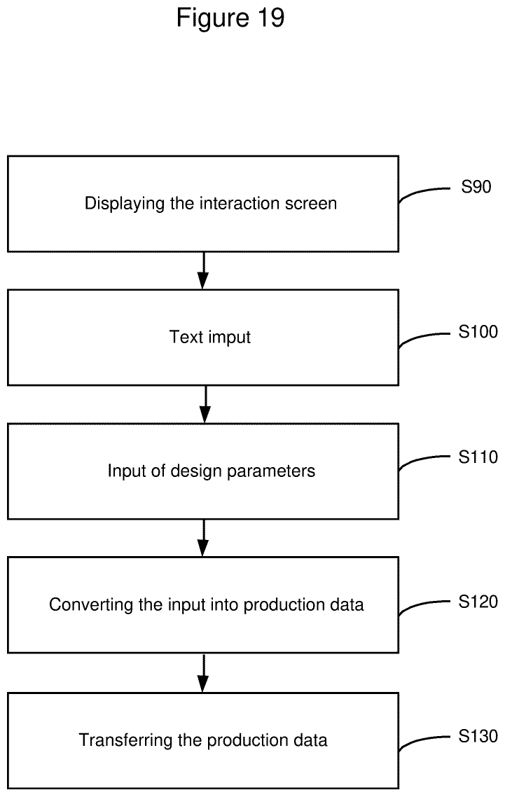

FIG. 21 shows a schematic diagram of a server by means of which the application of the present invention is supported

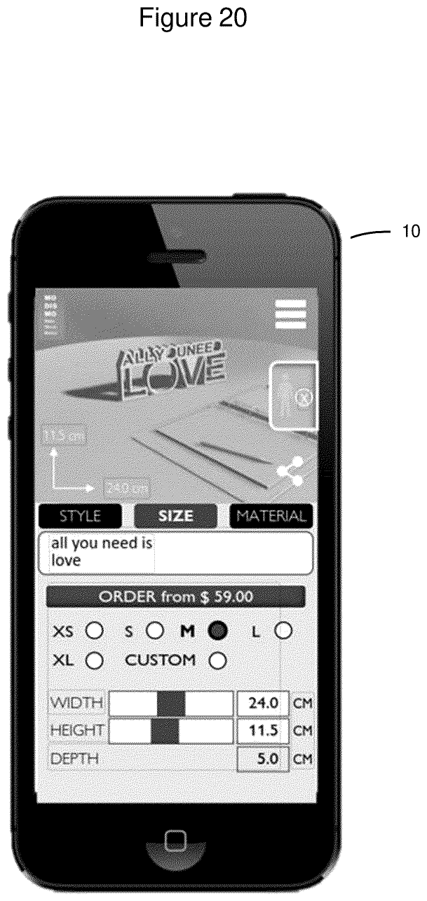

FIG. 22 shows a flowchart illustrating individual steps performed using the server shown in FIG. 20

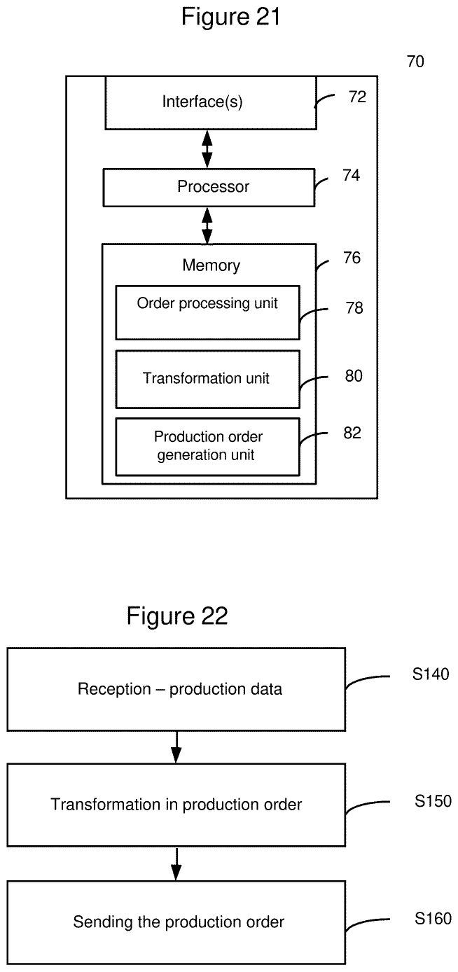

1.-29. (canceled)

30. A method of producing a three-dimensional structure representing a character string having at least one character, comprising:
creating an offset contour such that the offset contour has a predetermined distance (A) from the main contour of each character such that an offset area results between the main contour and the offset contour;
creating an overall offset contour from the offset contours of the characters of the string in such a manner that the offset areas assigned to the characters touch and/or overlap;
creating a monolith surface as a contiguous surface between the main contours of the characters and the overall offset contour; and
extruding the monolith surface into a monolith volume to form a monolith that is readable by the volumes of characters cut from it and bounded by the overall offset contour.

31. The method of claim 30, further comprising converting a standard format of each predetermined character of the string into at least one associated geometrically processable main contour.

32. The method of claim 30, further comprising eliminating at least one internal contour comprised by the main contour of each character.

33. The method according to claim 30, further comprising grouping the main contour of each character with at least one outlying contour associated with the main contour of the character.

34. The method according to claim 30, characterized in that extruding is carried out by means of laser cutting, water jet cutting, CNC milling, 3D printing, casting or injection molding or other machine manufacturing processes.

35. The method according to claim 30, characterized in that the offset contours of the characters are formed between contours or main contours and offset contours of the characters.

36. The method according to claim 30, characterized in that non-overlapping internal portions of the offset surfaces are removed from the monolith.

37. The method according to claim 30, characterized in that the method is carried out by means of a computer.

38. The method according to claim 30, further comprising adding further elements to the monolith to obtain an object.

39. The method according to claim 30, characterized in that the contours or main contours and offset contours of the characters are converted into a vector format or used as such.

40. The method according to claim 30, characterized in that ASCII characters in any language or special characters are used alone or in combination as characters.

41. The method according to claim 30, characterized in that the character string is formed with characters whose size varies.

42. The method according to claim 30, characterized in that the character string is arrayed as a block with the same line width.

43. Application of the method according to claim 42, characterized in that, after specifying the desired character sequence, its dimension and the material, an application carries out the shaping process via a manufacturing file.

44. A three-dimensional structure representing a character string obtainable by the method claim 30.
